(19) United States
(12) Patent Application Publication
(10) Pub. No.: US 2019/0067352 A1
(43) Pub. Date: Feb. 28, 2019

(54) PHOTOSENSITIVE CHIP PACKAGING STRUCTURE AND PACKAGING METHOD THEREOF

(71) Applicant: China Wafer Level CSP Co., Ltd, Suzhou, Jiangsu (CN)

(72) Inventors: Zhiqi Wang, Suzhou (CN); Guoliang Xie, Suzhou (CN)

(73) Assignee: China Wafer Level CSP Co., Ltd., Suzhou, Jiangsu (CN)

(21) Appl. No.: 15/766,781

(22) PCT Filed: Oct. 28, 2016
(86) PCT No.: PCT/CN2016/103791

§ 371 Date: Apr. 6, 2018

(30) Foreign Application Priority Data
Oct. 29, 2015 (CN) 201510726417.0
Oct. 29, 2015 (CN) 201520857975.6

(51) Int. Cl. H01L 27/146; H01L 23/00

(52) U.S. Cl. CPC H01L 27/14623; H01L 27/14618; H01L 27/14685; H01L 27/14687; H01L 24/02; H01L 2224/13024; H01L 27/14636; H01L 2224/02372; H01L 2224/02381; H01L 2224/02371; H01L 24/13

(57) ABSTRACT

An image sensor chip package and a packaging method thereof are provided. The image sensor chip package includes: an image sensor chip having a first surface and a second surface opposite to each other, a photosensitive region being arranged on the first surface; a protective cover plate having a third surface and a fourth surface opposite to each other, the third surface covering the first surface; and a light shielding layer arranged on the fourth surface of the protective cover plate, the light shielding layer having an opening, and the photosensitive region being exposed through the opening. The light shielding layer includes a light absorbing layer located on the fourth surface and a metal layer located on the light absorbing layer.

This application claims the priority to Chinese Patent Application No. 201510726417.0, titled “PHOTOSENSITIVE CHIP PACKAGING STRUCTURE AND PACKAGING METHOD THEREOF” and filed with the Chinese State Intellectual Property Office on Oct. 29, 2015, and the priority to Chinese Patent Application No. 201520857975.6, titled “IMAGE SENSOR CHIP PACKAGE” and filed with the Chinese State Intellectual Property Office on Oct. 29, 2015, both of which are incorporated herein by reference in their entireties.

### FIELD

The present disclosure relates to the technical field of semiconductors, and in particular to an image sensor chip package and a packaging method thereof.

### BACKGROUND

With the development of light and shadow technologies such as a photography technology, there is a huge market demand for image sensor chips as functional chips for converting received light signals into electrical signals, which are generally applied to cameras of electronic products.

Furthermore, an image sensor chip packaging technology is rapidly developed, and the wafer level chip size packaging (WLCSP) technology is mainstream currently, in which a wafer is packaged and tested and then is cut to obtain individual finished chips. With the packaging technology, the individual packaged chip product almost has the same size as an individual crystalline grain, thus meeting the market requirement for lighter, smaller, shorter, thinner and cheaper microelectronic products. The wafer level chip size packaging (WLCSP) technology is a hotspot in the current packaging field and represents a development trend in the future.

A photosensitive region is arranged on a surface of the image sensor chip. In order to prevent the photosensitive region from being damaged and contaminated during a packaging process, the surface of the image sensor chip on which the photosensitive region is arranged is generally covered by a protective cover plate. The protective cover plate may be remained after the wafer level packaging and the cutting process, so as to protect the image sensor chip during subsequent processes and future operations.

The protective cover plate has a transparency, to facilitate acquisition of external light by the photosensitive region of the image sensor chip. However, the protective cover plate brings undesirable effects while protecting the image sensor chip. Generally, a light may be reflected in the interior of the protective cover plate after the light enters the protective cover plate, causing an undesirable image, a ghost and the like. A technical issue to be solved by those skilled in the art is how to eliminate these undesirable effects.

For example, reference is made to FIG. 1, which is a schematic diagram of a image sensor chip package according to the conventional technology. The image sensor chip package includes: an image sensor chip 10 having a first surface and a second surface opposite to each other; a photosensitive region 20 located on the first surface of the image sensor chip 10; a contact pad 21 located on the first surface of the image sensor chip 10 at a side of the photosensitive region 20; a through hole (not numbered) extending from the second surface of the image sensor chip 10 to the first surface of the image sensor chip 10, where the contact pad 21 is exposed through the through hole; an insulting layer 11 located on a sidewall of the through hole and the second surface of the image sensor chip 10; a metal wiring layer 12 located on a surface of the insulting layer 11 and at the bottom of the through hole, where the metal wiring layer 12 is electrically connected to the contact pad 21; a solder mask layer 13 covering the metal wiring layer 12 and the insulting layer 11, where the solder mask layer 13 has an opening; a solder ball 14 located in the opening of the solder mask layer 13 and electrically connected to the contact pad 21 through the metal wiring layer 12; a protective substrate 30 covering the first surface of the image sensor chip 10; and a support dam 31 arranged on the protective substrate 30 and located between the protective substrate 30 and the image sensor chip 10, where the photosensitive region is surrounded by the support dam 31.

In use of the image sensor chip described above, a light I1 is incident on the protective substrate 30, a part of the light I2 may reach a sidewall 30s of the protective substrate 30, resulting in light reflection on the sidewall. Imaging of the image sensor chip is interfered in a case where the reflected light is incident on the photosensitive region 20, especially in a case where an incident angle of the light I2 meets a certain condition. For example, in a case where the protective substrate 30 is made of glass and is surrounded by air outside, and an incident angle of the light I2 is greater than a critical angle of the light I2 for a glass-to-air interface, the light I2 may be totally reflected on the sidewall 30s of the protective substrate 30, and the total reflected light I2 propagates within the protective substrate 30 and is refracted to the photosensitive region 20, which results in serious interference to the photosensitive region 20, so that the image sensor chip generates an undesirable image or a ghost, thereby reducing imaging quality.

Furthermore, as the wafer level chip package becomes smaller, more image sensor chips are integrated on a wafer level chip, a size of an individual finished chip package is smaller, the sidewall of the protective substrate 30 is closer to an edge of the photosensitive region 20, and thus the interference described above becomes more serious.

### SUMMARY

In the present disclosure, the problem of an undesirable image, a ghost and the like generated by an image sensor chip is solved by improving a protective cover, thereby improving imaging quality of the image sensor chip.

In order to solve the problem described above, an image sensor chip package is provided according to the present disclosure, which includes: an image sensor chip having a first surface and a second surface opposite to each other, where a photosensitive region is arranged on the first surface; a protective cover plate having a third surface and a fourth surface opposite to each other, where the third surface covers the first surface; and a light shielding layer arranged on the fourth surface of the protective cover plate, where the light shielding layer has an opening, and the photosensitive region is exposed through the opening. The light shielding layer includes a light absorbing layer located on the fourth surface and a metal layer located on the light absorbing layer.

Preferably, the light absorbing layer is made of black glue.

Preferably, the light absorbing layer is made of black photosensitive glue.

Preferably, the metal layer is processed by surface blackening treatment.

Preferably, the metal layer is made of aluminum.

Preferably, a support dam is arranged on the third surface of the protective cover plate, where a hollow cavity is enclosed by the support dam and the third surface of the protective cover plate, and the photosensitive region is located in the hollow cavity.

Preferably, the image sensor chip package further includes: a contact pad arranged on the first surface and located outside the photosensitive region; a through hole extending from the second surface to the first surface, where the contact pad is exposed through the through hole; an insulating layer covering the second surface and a surface of a sidewall of the through hole; a metal wiring layer located on the insulating layer and at the bottom of the through hole, where the metal wiring layer is electrically connected to the contact pad; a solder mask layer located on the metal wiring layer and the insulating layer, where the solder mask layer has an opening, and the metal wiring layer is exposed from the bottom of the opening; and a solder ball filling the opening, where the solder ball is electrically connected to the metal wiring layer.

An image sensor chip packaging method is further provided according to the present disclosure, which includes: providing a wafer, where the wafer has multiple image sensor chips arranged in an array, the wafer has a first surface and a second surface opposite to each other, and photosensitive regions are arranged on the first surface; providing a substrate having multiple protective cover plates corresponding to the image sensor chips, where the substrate has a third surface and a fourth surface opposite to each other; aligning and laminating the wafer with the substrate, where the first surface is covered by the third surface; and cutting the wafer and the substrate to form multiple image sensor chip packages. A light shielding layer is formed on the fourth surface of the substrate, the light shielding layer has openings corresponding to the image sensor chips, and the photosensitive regions are exposed through the openings. The light shielding layer includes a light absorbing layer located on the fourth surface and a metal layer located on the light absorbing layer.

Preferably, the light absorbing layer is made of black glue, and the step of forming the light shielding layer includes: applying the black glue on the whole fourth surface of the substrate to form a black glue layer; depositing a metal material on the black glue layer to form a metal material layer; performing surface blackening treatment on the metal material layer; etching the openings on the metal material layer to form the metal layer; and etching the openings on the black glue layer by using the metal layer as a mask to form the light absorbing layer.

Preferably, the light absorbing layer is made of black photosensitive glue, and the step of forming the light shielding layer includes: applying the black photosensitive glue on the whole fourth surface of the substrate to form a black photosensitive glue layer; depositing a metal material on the black photosensitive glue layer to form a metal material layer; performing surface blackening treatment on the metal material layer; etching an opening on the metal material layer to form the metal layer; and forming an opening on the black photosensitive glue layer by using the metal layer as a photoresist layer with an exposure and development process to form the light absorbing layer.

Preferably, the metal layer is an aluminum layer.

Preferably, each of the image sensor chips further includes a contact pad arranged on the first surface and located outside the photosensitive region. After aligning and laminating the wafer with the substrate, the packaging method further includes: forming a through hole extending to the first surface on the second surface of the wafer, where the contact pad is exposed through the through hole; forming an insulating layer covering a second surface of the wafer and a surface of a sidewall of the through hole; forming a metal wiring layer located on the insulating layer and at the bottom of the through hole, where the metal wiring layer is electrically connected to the contact pad; forming a solder mask layer located on the metal wiring layer and the insulating layer, where the solder mask layer has an opening, and the metal wiring layer is exposed from the bottom of the opening; and forming a solder ball filling the opening, where the solder ball is electrically connected to the metal wiring layer.

The beneficial effect of the present disclosure is to overcome disadvantages of an undesirable image, a ghost and the like generated by an image sensor chip, by forming the light shielding layer on the protective cover plate of the image sensor chip package, thereby improving the imaging quality of the image sensor chip.

### BRIEF DESCRIPTION OF THE DRAWINGS

FIG. 1 is a schematic diagram of an image sensor chip package according to the conventional technology;

FIG. 2 is a schematic diagram of an image sensor chip package according to an embodiment of the present disclosure;

FIG. 3 is a schematic top view of a wafer;

FIG. 4 is a sectional view of the wafer in FIG. 3 along A-A1;

FIG. 5 is a schematic sectional view of a substrate according to an embodiment of the present disclosure;

FIGS. 6(a) to 6(e) show a flow of a process of forming a light shielding layer on a substrate according to an embodiment of the present disclosure;

FIGS. 7(a) to 7(e) show a flow of a process of forming a light shielding layer on a substrate according to another embodiment of the present disclosure;

FIG. 8 is a schematic diagram of a structure obtained after aligning and laminating a substrate with a wafer; and

FIG. 9 is a schematic diagram of a structure obtained after packaging a wafer.

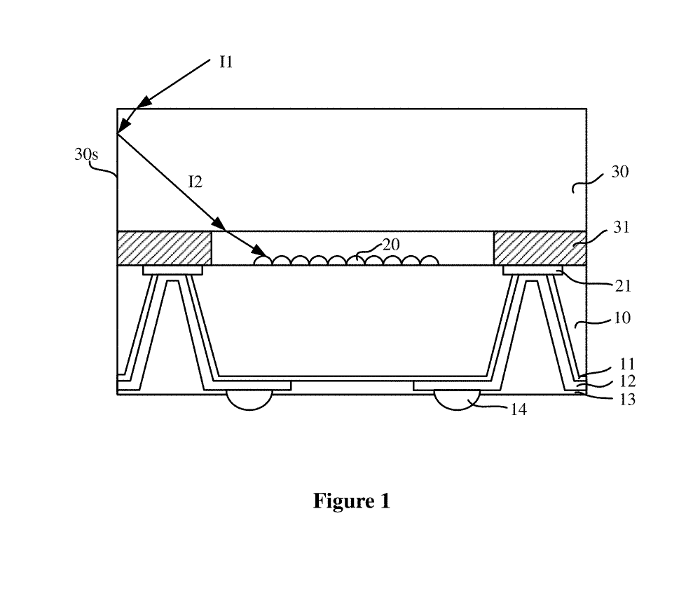

### DETAILED DESCRIPTION OF EMBODIMENTS

The embodiments of the present disclosure are described in detail hereinafter in conjunction with the drawings. The embodiments are not intended to limit the present disclosure, and changes made to structures, methods or functions by those skilled in the art according to the embodiments should fall within the protection scope of the present disclosure.

It should be noted that these drawings are provided for the purpose of aiding understanding of the embodiments of the present disclosure and should not be construed as unduly limiting the present disclosure. For the sake of clarity, the dimensions shown in the drawings are not drawn proportionally and may be enlarged, reduced, or otherwise altered. In addition, three-dimensional spatial sizes of a length, a width and a depth should be included in an actual production. Furthermore, a structure described below as that a first feature is “on” a second feature may include an embodiment in which the first feature and the second feature are formed in direct contact and may further include an embodiment in which an additional feature is formed between the first feature and the second feature, in which case the first and second features may not be in direct contact.

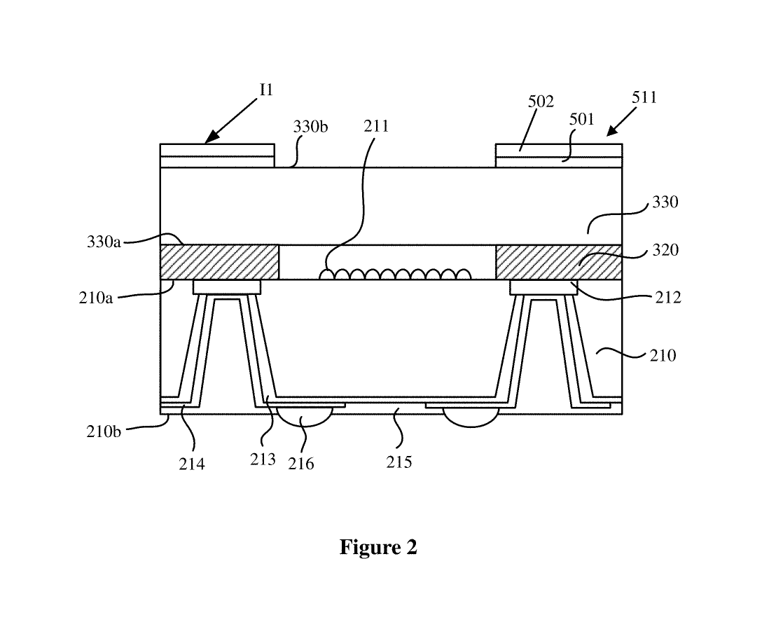

Reference is made to FIG. 2, which is a schematic diagram of an image sensor chip package according to an embodiment of the present disclosure. The image sensor chip package includes: an image sensor chip 210 having a first surface 210a and a second surface 210b opposite to each other, where a photosensitive region 211 is arranged on the first surface 210a; and a protective cover plate 330 having a third surface 330a and a fourth surface 330b opposite to each other, where the third surface 330a covers the first surface 210a. A support dam 320 is arranged on the third surface 330a. The support dam 320 is located between the protective cover plate 330 and the image sensor chip 210. The photosensitive region 211 is located in a hollow cavity enclosed by the support dam 320 and the third surface 330a of the protective cover plate 330.

A light shielding layer 511 is arranged on the fourth surface 330b of the protective cover plate 330. The light shielding layer 511 has an opening, through which a region of the fourth surface 330b corresponding to the photosensitive region 211 is exposed. That is, the photosensitive region 211 is exposed through the opening. In some embodiments, an area of the opening is equal to or greater than an area of the photosensitive region 211, and a light incident from the opening to the protective cover plate 330 may penetrate through the protective cover plate 330 and enter into the photosensitive region 211, thereby avoiding the interference of the light shielding layer 511 to the photosensitive region 211.

The light shielding layer 511 includes a light absorbing layer 501 located on the fourth surface 330b of the protective cover plate 330 and a metal layer located on the light absorbing layer 501. The light absorbing layer 501 is mainly used to absorb the light projected to the fourth surface 330b from the interior of the protective cover plate 330. The metal layer 502 is mainly used to prevent a light incident from outside to the light shielding layer 511 from entering the interior of the protective cover plate 330 and to provide protection for the light absorbing layer 501.

In the embodiment, the light absorbing layer 501 is made of black photosensitive glue or black glue. The metal layer 502 is made of aluminum, and the metal layer 502 is processed by surface blackening treatment, thereby preventing interference to imaging quality of the image sensor chip 210 due to a specular reflection of light incident on the surface of the metal layer 502.

Since the light absorbing layer 501 is made of a soft organic material, the light absorbing layer 501 without the metal layer 502 may be scratched easily in subsequent processes. Since the metal layer 502 is hard enough to well resist scratch and wear, the light absorbing layer 501 can be prevented from being scratched in subsequent processes by forming the metal layer 502 on the light absorbing layer 501.

Since the metal layer 502 is opaque to light, the light absorbing layer 501 may be thinned and may be made of an absorbent material with a low absorption rate. Without the metal layer 502, the light absorbing layer 501 is required to have a high absorption rate. For example, only an absorption rate higher than 95% can achieve a good shading effect. By adding the metal layer 502, the requirement on the absorption rate of the light absorbing layer is reduced. An absorbent material with an absorption rate of 90% can be selected to achieve a good shading effect. Since an absorbent material with a high absorption rate results in a high cost, the cost is reduced by adding the metal layer 502.

A contact pad 212 is arranged on the first surface 210 of the image sensor chip 210 and is located outside the photosensitive region 211. In the embodiment, the image sensor chip 210 is provided with: a through hole extending from the second surface 210b of the image sensor chip 210 to the first surface 210a, where the contact pad 212 is exposed through the through hole; an insulating layer 213 located on the second surface 210b and a sidewall of the through hole; a metal wiring layer 214 located on the insulating layer 213 and at the bottom of the through hole, where the metal wiring layer 214 is electrically connected to the contact pad 212; a solder mask layer 215 located on the metal wiring layer 214 and the insulating layer 213, where the solder mask layer 215 has an opening, the metal wiring layer 214 is exposed from the bottom of the opening; and a solder ball 216 filling the opening, where the solder ball 216 is electrically connected to the metal wiring layer 214. In this way, the contact pad 212 is electrically connected to the solder ball 216 through the metal wiring layer 214. By electrically connecting the solder ball 214 to other external circuits, the electrical connection between the image sensor chip 210 and the other external circuits is realized.

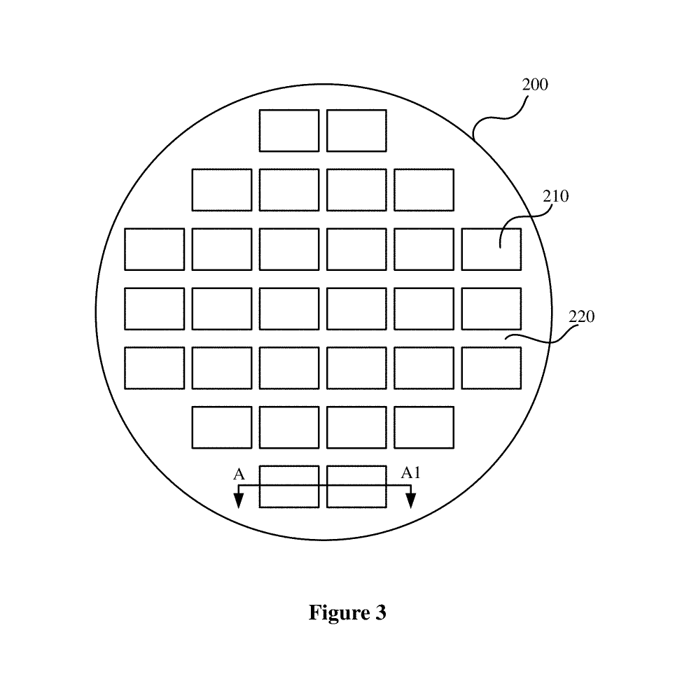

Correspondingly, an image sensor chip packaging method is provided according to the embodiment of the present disclosure to form the image sensor chip package shown in FIG. 2. Reference is made to FIGS. 3 to 9, which are schematic diagrams of intermediate structures formed during the packaging process according to the embodiment of the present disclosure.

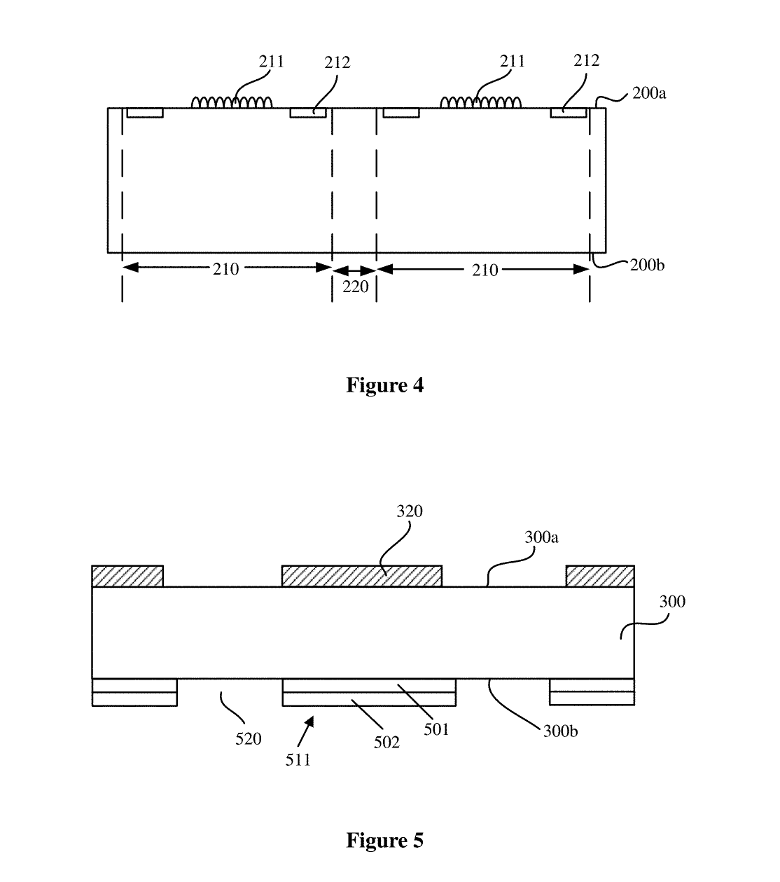

First, referring to FIGS. 3 and 4, a wafer 200 is provided. FIG. 3 is a schematic top view of the structure of the wafer 200, and FIG. 4 is a sectional view of the wafer 200 in FIG. 3 along A-A1.

The wafer 200 has a first surface 200a and a second surface 200b opposite to each other. The wafer 200 includes multiple image sensor chips 210 arranged in an array and cutting trench regions 220 located between adjacent image sensor chips 210. After the wafer 200 is packaged, the wafer 200 is cut along the cutting trench regions 220 to form multiple image sensor chip packages.

The image sensor chip 210 includes a photosensitive region 211 and contact pads 212 located outside the photosensitive region 211. The photosensitive region 211 may include multiple photodiodes arranged in an array for converting light signals irradiated to the photosensitive region 211 to electrical signals. The contact pads 212 serve as an input terminal and an output terminal for connecting components in the photosensitive region 211 to external circuits. The image sensor chip 210 may further include other functional components, which are not limited in the present disclosure. Any semiconductor chip with an image sensing function is considered as the image sensor chip in the present disclosure.

It should be noted that, for the subsequent steps of the packaging method according to the embodiment of the present disclosure, for the sake of clarity and simplicity, the description is only made with the example of the sectional view of the wafer 200 in the direction of A-A1 as shown in FIG. 3, and similar steps are also performed in other regions.

Next, referring to FIG. 5, a substrate 300 is provided. The substrate 300 covers the first surface 200a of the wafer 200 in subsequent processes to protect the photosensitive region 211 on the wafer 200.

Since the light is required to reach the photosensitive region 211 through the substrate 300, the substrate 300 is made of a transparent material and has a high transmission rate. Specifically, the substrate 300 may be made of inorganic glass, organic glass or other transparent materials with specific strength.

In addition, in order to ensure high strength and transmission performance of the substrate 300, there is a certain requirement on a thickness of the substrate. In the embodiment, the thickness of the substrate 300 ranges from 50 μm to 500 μm, for example, the thickness of the substrate 300 may be 400 μm.

The substrate 300 has a third surface 300a and a fourth surface 300b opposite to each other, the two surfaces 300a and 300b of the substrate 300 are flat and smooth, so as not to cause scattering, diffuse reflection and the like of an incident light. The substrate 300 is remained as the protective cover plate 330 of the image sensor chip 210 after the packaging process and the cutting process.

Multiple support dams 320 are formed on the third surface 300a of the substrate 300. Multiple hollow cavities arranged in an array are enclosed by the support dams 320 and the third surface 300a of the substrate 300, where each of the hollow cavities corresponds to a photosensitive region 211.

A light shielding layer 511 is formed on the fourth surface 300b of the substrate 300. The light shielding layer 511 includes multiple openings 520 corresponding to the photosensitive regions 211. The opening 520 has an area greater than or equal to that of the photosensitive region 211, for exposing the photosensitive region 211 after the package is formed.

The light shielding layer 511 includes a light absorbing layer 501 located on the fourth surface 300b of the substrate 300 and a metal layer 502 located on the light absorbing layer 501.

The light absorbing layer 501 is made of black organic material which is opaque or low transparent, such as black glue or black photosensitive glue. The black glue refers to non-photosensitive black glue generally used in a semiconductor process, such as epoxy resin glue. The black photosensitive glue refers to photosensitive organic glue generally used in a semiconductor process.

The metal layer 502 is located on another surface of the light absorbing layer 501 which is not in contact with the fourth surface 300b. The metal layer 502 may be processed by surface blackening treatment, so that a specular reflection of light cannot occur on the surface of the metal layer 502. The metal layer 502 may be made of aluminum, aluminum alloy or other suitable metal materials.

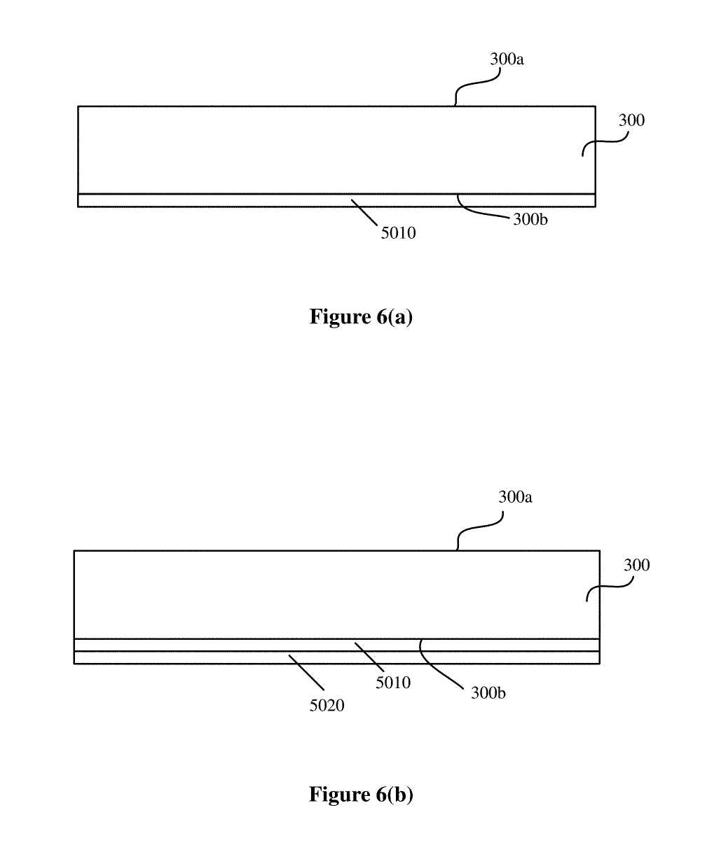

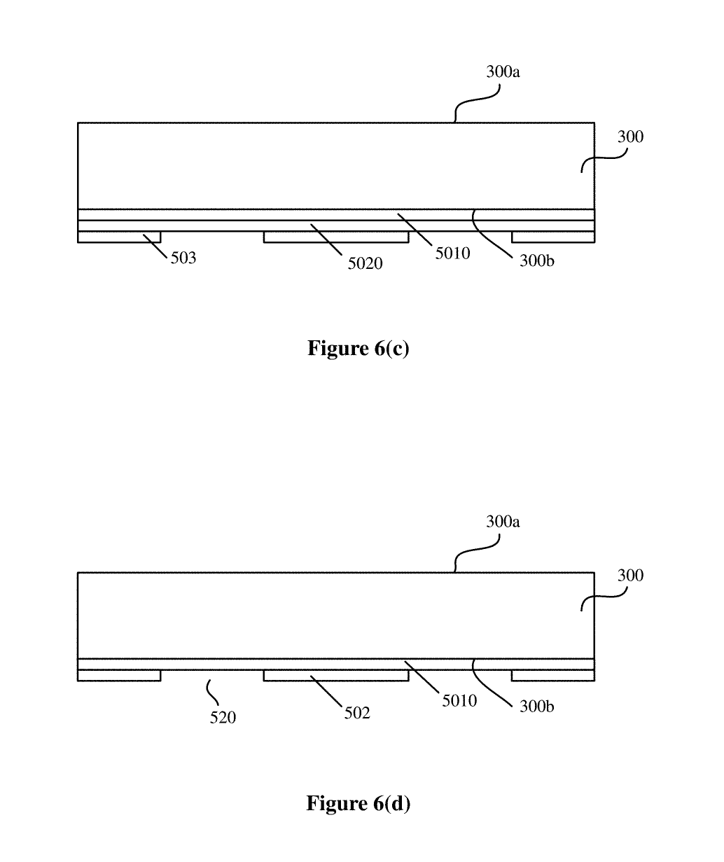

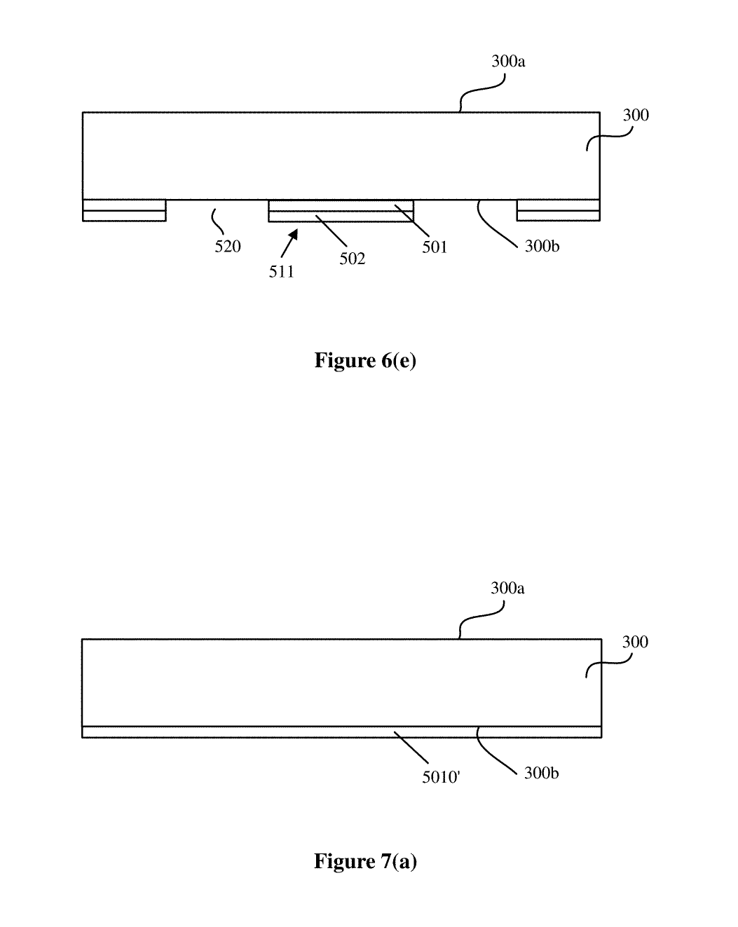

In a case where the light absorbing layer is made of the black glue, the process of forming the light shielding layer 511 is as follows, referring to FIGS. 6(a) to 6(e).

As shown in FIG. 6(a), the black glue is applied on the whole fourth surface 300b of the substrate 300 with a spin-coating process to form a black glue layer 5010.

As shown in FIG. 6(b), a metal material is deposited on the black glue layer 5010 to form a metal material layer 5020, and the metal material layer 5020 is processed by surface blackening treatment.

As shown in FIG. 6(c), a patterned photoresist layer 503 is formed on the metal material layer 5020.

As shown in FIG. 6(d), an opening is etched on the metal material layer 5020 to form a patterned metal layer 502.

As shown in FIG. 6(e), an opening is etched on the black glue layer 5010 by a dry etching process using the metal layer 502 as a mask to form a patterned light absorbing layer 501.

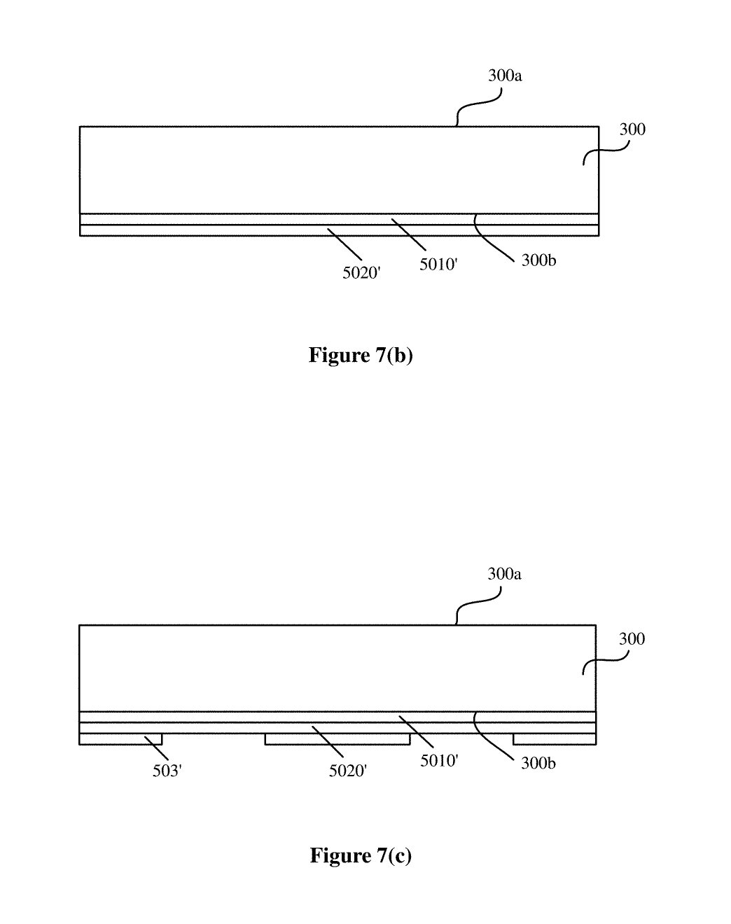

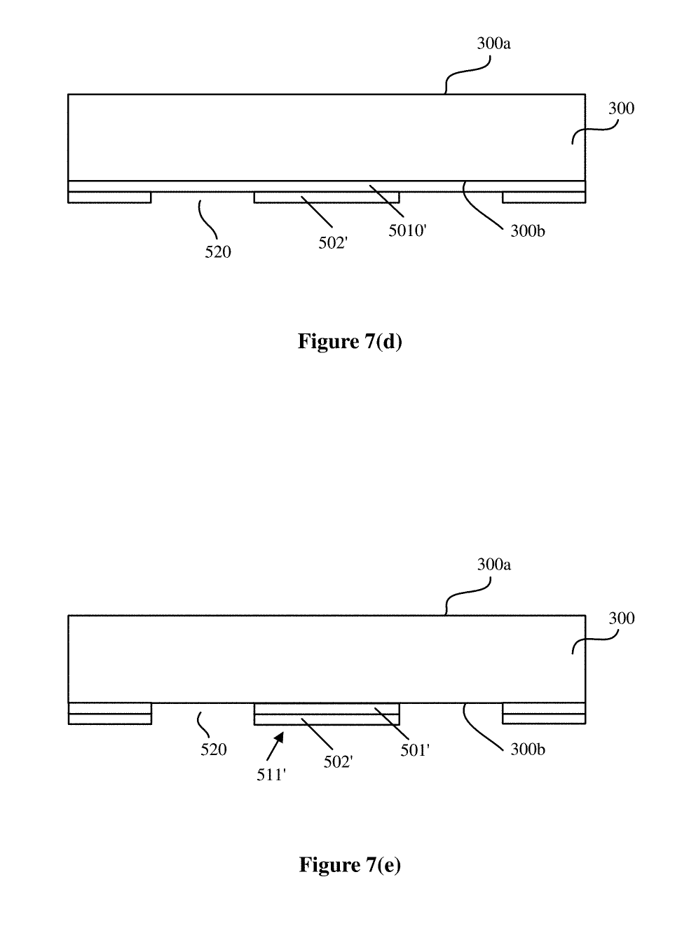

In a case where the light absorbing layer is made of the black photosensitive glue, the process of forming a light shielding layer 511′ is as follows, referring to FIGS. 7(a) to 7(e).

As shown in FIG. 7(a), the black photosensitive glue is applied on the whole fourth surface 300b of the substrate 300 with the spin-coating process to form a black photosensitive glue layer 5010′.

As shown in FIG. 7(b), a metal material is deposited on the black photosensitive glue layer 5010′ to form a metal material layer 5020′ and the metal material layer 5020′ is processed by surface blackening treatment.

As shown in FIG. 7(c), a patterned photoresist layer 503′ is formed on the metal material layer 5020′.

As shown in FIG. 7(d), an opening is etched on the metal material layer 5020′ to form a patterned metal layer 502′.

As shown in FIG. 7(e), an opening is formed on the black glue layer 5010′ by an exposure and development process using the metal layer 502′ as a mask to form a patterned light absorbing layer 501′.

In the embodiment, the metal layer 502 (or the metal layer 502′) is an aluminum layer, and the aluminum layer is processed by surface blackening treatment with an acid-base solution. For example, the aluminum layer may be processed with a sulfur-based alkali solution to form a black sulfide film layer on the aluminum layer, thereby improving the anti-specular reflection performance of the aluminum layer. In some embodiments, the thickness of the metal layer subjected to the surface blackening treatment ranges from 1 μm to 10 μm.

In some embodiments, a thickness of the light absorbing layer ranges from 1 μm to 10 μm.

It should be noted that in other embodiments, the step of forming the light shielding layer 511 on the fourth surface 300b of the substrate 300 may be performed after the wafer 200 is aligned and laminated with the substrate 300, or before the support dam 320 is formed on the substrate 300, which is not limited in the present disclosure and may be selected according to specific process conditions.

In the embodiment, the support dam 320 is made of photoresists glue. The photoresists glue is applied on the third surface 300a of the substrate 300 with a spray-coating process or a spin-coating process to form a photoresists glue layer, and the photoresists glue layer is patterned with an exposure and development process to form multiple support dams 320 arranged in an array. In some embodiments, the support dam 320 may also be made of silicon oxide, silicon nitride, silicon oxynitride and other insulating medium materials, which may be deposited by a depositing process and then patterned by a lithography and etching process to form multiple support dams 320 arranged in an array.

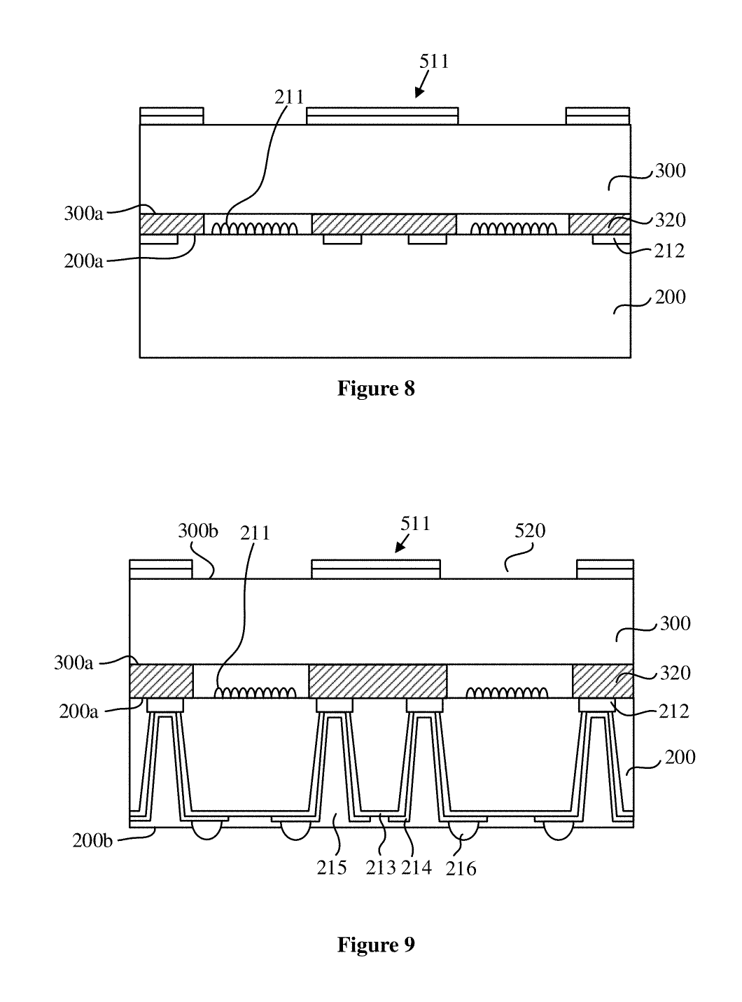

Next, referring to FIG. 8, the third surface 300a of the substrate 300 is aligned and laminated with the first surface 200a of the wafer 200. A hollow cavity (not marked) is enclosed by the support dam 320 and the third surface 300a of the substrate 300, and the photosensitive region 211 is located in the hollow cavity.

In the embodiment, the substrate 300 is aligned and laminated with the wafer 200 through an adhesive layer (not shown). For example, the adhesive layer may be formed on a top surface of the support dam 320 with a screen printing process or a spin-coating process, and then the third surface 300a of the substrate 300 and the first surface 200a of the wafer 200 are aligned and laminated, to be bonded together through the adhesive layer. The adhesive layer functions not only for adhering, but also for insulating and sealing. The adhesive layer may be made of a polymer bonding material, such as silica gel, epoxy resin, benzocyclobutene or other polymer materials.

In the embodiment, after the third surface 300a of the substrate 300 is bounded with the first surface 200a of the wafer 200, a hollow cavity is enclosed by the support dam 320 and the first surface 200a of the wafer 200. A position of the hollow cavity corresponds to a position of the photosensitive region 211, and an area of the hollow cavity is slightly greater than an area of the photosensitive region 211, such that the photosensitive region 211 is located in the hollow cavity. In the embodiment, after the substrate 300 and the wafer 200 are bonded, the contact pad 212 on the wafer 200 is covered by the support dam 320 of the substrate 300. The substrate 300 may protect the wafer 200 in subsequent processes.

Next, referring to FIG. 9, the wafer 200 is packaged.

First, the wafer 200 is thinned on the second surface 200b of the wafer 200, to facilitate subsequent etching of the through hole. The wafer 200 may be thinned with a mechanical polishing process, a chemical mechanical polishing process and the like. Then, the wafer 200 is etched on the second surface 200b of the wafer 200 to form the through hole (not marked), where the contact pad 212 on the side of the first surface 200a of the wafer 200 is exposed through the through hole. Next, the insulating layer 213 is formed on the second surface 200b of the wafer 200 and the sidewall of the through hole, where the contact pad 212 located at the bottom of the through hole is not covered by the insulating layer 213, and the insulating layer 213 may provide electrical insulation for the second surface 200b of the wafer 200 and the substrate of the wafer 200 exposed by the through hole. The insulating layer 213 may be made of silicon oxide, silicon nitride, silicon oxynitride or insulating resin. Next, the metal wiring layer 214 connected to the contact pad 212 is formed on the surface of the insulating layer 213, such that the contact pad 212 is led to the second surface 200b of the wafer 200 and is connected to external circuits, where the metal wiring layer 214 is formed by depositing a metal film and etching the metal film. Next, the solder mask layer 215 having an opening (not marked) is formed on the surface of the metal wiring layer 214 and the surface of the insulating layer 213, where a part of the surface of the metal wiring layer 214 is exposed by the opening. The solder mask layer 215 is made of silicon oxide, silicon nitride or other insulating materials and is used to protect the metal wiring layer 214. Next, a solder ball 216 is formed on the surface of the solder mask layer 215, where the solder ball 216 fills the opening. The sold ball 216 may be a solder ball, a metal column and other connection structures, which may be made of copper, aluminum, gold, tin, lead or other metal materials.

After the wafer 200 is packaged, a chip package obtained with a cutting process may be connected to an external circuit through the solder ball 216. After light signals are converted to electrical signals by the photosensitive region 211 of the image sensor chip, the electrical signals may be transmitted through the contact pad 212, the metal wiring layer 214 and the solder ball 216 sequentially to the external circuit for being processed.

Multiple packages as shown in FIG. 2 are formed through a cutting process.

It should be understood that although the description of the embodiments is made in the specification, each of the embodiments does not merely one independent technical solution. The description manner of the specification is merely for the sake of clarity and the skilled in the art should take the specification as a whole. Technical solutions in the embodiments may also be appropriately combined to form other embodiments that can be understood by those skilled in the art.

The series of detailed descriptions set forth above are merely specific descriptions of the feasible embodiments of the present disclosure and are not intended to limit the protection scope of the present disclosure. Any equivalent embodiment or modification made without departing from the technical spirit of the present disclosure should fall within the protection scope of the present disclosure.

1. An image sensor chip package, comprising:
an image sensor chip having a first surface and a second surface opposite to each other, a photosensitive region being arranged on the first surface;
a protective cover plate having a third surface and a fourth surface opposite to each other, the third surface covering the first surface; and
a light shielding layer arranged on the fourth surface of the protective cover plate, the light shielding layer having an opening, and the photosensitive region being exposed through the opening, wherein
the light shielding layer comprises a light absorbing layer located on the fourth surface and a metal layer located on the light absorbing layer.

2. The image sensor chip package according to claim 1, wherein the light absorbing layer is made of black glue.

3. The image sensor chip package according to claim 1, wherein the light absorbing layer is made of black photosensitive glue.

4. The image sensor chip package according to claim 1, wherein the metal layer is processed by surface blackening treatment.

5. The image sensor chip package according to claim 4, wherein the metal layer is made of aluminum.

6. The image sensor chip package according to claim 1, wherein a support dam is arranged on the third surface of the protective cover plate, wherein a hollow cavity is enclosed by the support dam and the third surface of the protective cover plate, and the photosensitive region is located in the hollow cavity.

7. The image sensor chip package according to claim 1, further comprising:
a contact pad arranged on the first surface and located outside the photosensitive region;
a through hole extending from the second surface to the first surface, the contact pad being exposed through the through hole;
an insulating layer covering the second surface and a surface of a sidewall of the through hole;
a metal wiring layer located on the insulating layer and at the bottom of the through hole, the metal wiring layer being electrically connected to the contact pad;
a solder mask layer located on the metal wiring layer and the insulating layer, the solder mask layer having an opening, and the metal wiring layer being exposed from the bottom of the opening; and
a solder ball filling the opening, the solder ball being electrically connected to the metal wiring layer.

8. An image sensor chip packaging method, comprising:
providing a wafer, wherein the wafer has a plurality of image sensor chips arranged in an array, the wafer has a first surface and a second surface opposite to each other, and photosensitive regions are arranged on the first surface;
providing a substrate having a third surface and a fourth surface opposite to each other;
aligning and laminating the wafer with the substrate, wherein the first surface is covered by the third surface; and
cutting the wafer and the substrate to form a plurality of the image sensor chip packages according to claim 1; wherein
a light shielding layer is formed on the fourth surface of the substrate, the light shielding layer has openings corresponding to the image sensor chips, and the photosensitive regions are exposed through the openings; and
the light shielding layer comprises a light absorbing layer located on the fourth surface and a metal layer located on the light absorbing layer.

9. The image sensor chip packaging method according to claim 8, wherein the light absorbing layer is made of black glue, and the step of forming the light shielding layer comprises:
applying the black glue on the whole fourth surface of the substrate to form a black glue layer;
depositing a metal material on the black glue layer to form a metal material layer;
performing surface blackening treatment on the metal material layer;
etching the openings on the metal material layer to form the metal layer; and
etching the openings on the black glue layer by using the metal layer as a mask to form the light absorbing layer.

10. The packaging method according to claim 8, wherein the light absorbing layer is made of black photosensitive glue, and the step of forming the light shielding layer comprises:
applying the black photosensitive glue on the whole fourth surface of the substrate to form a black photosensitive glue layer;
depositing a metal material on the black photosensitive glue layer to form a metal material layer;
performing surface blackening treatment on the metal material layer;
etching the openings on the metal material layer to form the metal layer; and
forming the openings on the black photosensitive glue layer by an exposure and development process using the metal layer as a photoresist layer to form the light absorbing layer.

11. The packaging method according to claim 9, wherein the metal layer is an aluminum layer.

12. The packaging method according to claim 8, wherein each of the image sensor chips further comprises a contact pad arranged on the first surface and located outside the photosensitive region; and wherein after aligning and laminating the wafer with the substrate, the packaging method further comprises:
forming a through hole extending to the first surface on the second surface of the wafer, the contact pad being exposed through the through hole;
forming an insulating layer covering a second surface of the wafer and a surface of a sidewall of the through hole;
forming a metal wiring layer located on the insulating layer and at the bottom of the through hole, the metal wiring layer being electrically connected to the contact pad;
forming a solder mask layer located on the metal wiring layer and the insulating layer, the solder mask layer having an opening, and the metal wiring layer being exposed from the bottom of the opening; and
forming a solder ball filling the opening, the solder ball being electrically connected to the metal wiring layer.

13. The packaging method according to claim 10, wherein the metal layer is an aluminum layer.
